(19) United States
(12) Patent Application Publication
(10) Pub. No.: US 2026/0353750 A1
(43) Pub. Date: Nov. 5, 2026

(54) METHOD OF MANUFACTURING A SEMICONDUCTOR DEVICE

(71) Applicant: Infineon Technologies Austria AG, Villach (AT)

(72) Inventors: Murugalogeswaran Permal, Sungkai (MY); Ai Loon Ooi, Tanjong Tokong (MY); Oliver Humbel, Maria Elend (AT); Richard Gaisberger, Velden (AT); Hiroshi Narahashi, Villach (AT); Chi Eng New, Kulim (MY); Muhammad Musoddiq Jaafar, Kuala Lumpur (MY); Lena Anne Bergmann, Villach (AT)

(21) Appl. No.: 19/667,721

(22) Filed: May 5, 2026

(30) Foreign Application Priority Data
May 5, 2025 (DE) 102025117124.6

(51) Int. Cl. H10D 64/00; H10D 64/01

(52) U.S. Cl. CPC H10D 64/118; H10D 64/01

(57) ABSTRACT

A method of manufacturing a semiconductor device is described herein as well as a semiconductor device manufactured accordingly. Firstly, a semiconductor body including a part of each of an active region configured to conduct a load current and a termination region surrounding the active region may be provided. The active region includes at least one power cell structure with a plurality of trenches extending into the semiconductor body and arranged adjacent to each other along a first lateral direction in the active region at the first surface. A charge shielding layer is formed on the first surface including the at least one power cell structure within the active region and the termination region. The charge shielding layer is removed from the first surface at least in the region of the power cell structure by applying a two-step etching process to the charge shielding layer.

### TECHNICAL FIELD

The present disclosure relates in general to a method of manufacturing a semiconductor device, in particular a power semiconductor device with an edge termination region, and a semiconductor device manufactured accordingly.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a load current along a load current path between two load terminals of the device. Further, the load current path may be controlled by means of an insulated electrode, sometimes referred to as gate electrode. For example, upon receiving a corresponding control signal from, e.g., a driver unit, the control electrode may set the power semiconductor device in one of a conducting state and a blocking state.

In some cases, the gate electrode may be included within a trench of the power semiconductor device, wherein the trench may exhibit, e.g., a stripe configuration or a needle configuration. Further, such trench occasionally includes more than only one electrode, e.g., two or more electrodes that are arranged separately from each other and sometimes also electrically insulated from each other. For example, a trench may comprise both a gate electrode and a field electrode, wherein the gate electrode can be electrically insulated from each of the load terminals, and wherein the field electrode can be electrically connected to one of the load terminals.

A vertical power semiconductor device is a semiconductor device in which active regions with the gate and filed electrodes mainly extend in a horizontal plane of the semiconductor body. In such vertical power semiconductor devices, the active region usually does not extend to the edge surface of the semiconductor body. Instead, the active region is distant to the edge surface of the semiconductor body in a lateral direction. In this case, a semiconductor region (edge region) of the semiconductor body adjoining the active region in the lateral direction also has to withstand the voltage applied to the active region of the semiconductor device.

The edge region may be implemented with a planar edge termination structure that includes a passivation layer formed on top of a surface of the semiconductor body in an edge region of the semiconductor body. Passivation layers can have the effect of charge shielding layers (CSL) which play a critical role at the edge termination, ensuring reliability performance, especially in scenarios like High Temperature Reverse Bias (HTRB). Charge shielding layers are used to block external ions that could disrupt the electric field, potentially causing avalanche breakdown within the device.

There is therefore a need for a semiconductor device with an active region with trench structures and an edge termination region that ensures reliable performance and a manufacturing process for a reliable semiconductor device.

### SUMMARY

According to an embodiment, a method of manufacturing a semiconductor device comprises a multistep process for providing a charge shielding layer above the edge termination region of a semiconductor device. More particularly, a semiconductor body having a first surface may be provided wherein the semiconductor body comprises a part of each of an active region configured to conduct a load current and a termination region surrounding the active region.

At least one power cell structure may be formed with a plurality of trenches extending into the semiconductor body and arranged adjacent to each other along a first lateral direction in the active region at the first surface. Each of the plurality of trenches may include a trench electrode, each of the trenches may have a stripe configuration that extends along a second lateral direction into the active region, and the trenches may spatially confine a plurality of mesas. The mesas may comprise contact holes.

A nitride charge shielding layer may be formed on the first surface comprising the at least one power cell structure within the active region and the termination region. The charge shielding layer may be removed from the first surface at least in the region of the power cell structure by applying a first etching process to the charge shielding layer at least until the trenches and/or contact holes of the power cell structure are open, that means being substantially free of charge shielding layer material. Substantially free means in this context that the material of the charge shielding layer deposited inside the trenches or contact holes is etched away in the holes until the bottom of the trench is no longer covered. In most cases, some residuals of the material of the charge shielding layer in the areas at the trench walls or the upper parts of the trench walls (also called spacers) may not be removed by this first etching step.

A second etching process different to the first etching process may be applied to the charge shielding layer remaining after the first etching for removing the residuals of the nitride layer from the first surface in the region of the power cell structure. In some cases, these residuals to be removed in the second step are at the upper trench wall areas while the bottom of the trenches usually are free of residuals after the first etching process.

According to another embodiment, a semiconductor device formed by the method as described herein is disclosed.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 schematically illustrates a general concept of the method of manufacturing a semiconductor device.

FIG. 2 illustrates a vertical cross-sectional view of one section of a semiconductor device according to an example.

FIG. 3 illustrates a top view of a semiconductor body according to one example.

FIG. 4 illustrates examples of intermediate process steps of the method according to an example.

FIGS. 5A and 5B illustrate cross sectional views of the contact hole after anisotropic etching using two different etching procedures.

FIGS. 6A and 6B illustrate cross sectional views of the contact hole after isotropic etching using two different etching procedures.

FIGS. 7A, 7B, 7C, and FIG. 7D illustrate cross-sectional views of the termination section of a semiconductor device during a preparation method according to an example. FIG. 7A shows the device before the removal step of the CSL, FIG. 7B the same device after the etching step, FIG. 7C the device after the removal of the mask, and FIG. 7D the device after the deposition of further insulating or semi insulating layers.

FIG. 8 illustrates a cross-sectional view of the termination section of a semiconductor device according to another embodiment described herein.

FIGS. 9A and 9B schematically show the layer structure above the semiconductor body surface achieved in the termination region in a device with CSL prepared according to a common method (FIG. 9A) compared to a device prepared according to the method described herein (FIG. 9B).

### DETAILED DESCRIPTION

In the following detailed description, reference is made to the accompanying drawings which form a part hereof and which are shown by way of illustration of specific embodiments in which the invention may be practiced. For example, features illustrated or described as part of one embodiment can be used on or in conjunction with other embodiments to yield yet a further embodiment. It is intended that the present invention includes such modifications and variations.

In this regard, directional terminology, such as ´top´, ´bottom´, ´below´, ´front´, ´behind´, ´back´, ´leading´, ´trailing´, ´above´ etc., may be used with reference to the orientation of the figures being described. Because parts of embodiments can be positioned in a number of different orientations, the directional terminology is used for purposes of illustration and is in no way limiting.

The term ´horizontal´ as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term ´vertical´ as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as ´vertical direction Z´ herein.

In this specification, n-doped is referred to as ´first conductivity type´ while p-doped is referred to as ´second conductivity type´. Alternatively, opposite doping relations can be employed so that the first conductivity type can be p-doped, and the second conductivity type can be n-doped.

Specific embodiments described in this specification pertain to, without being limited thereto, a power semiconductor device exhibiting a stripe cell or cellular cell configuration, e.g., a power semiconductor device that may be used within a power converter or a power supply. Thus, in an embodiment, such device can be configured to carry a load current that is to be fed to a load and/or, respectively, that is provided by a power source. For example, the power semiconductor device may comprise one or more active power semiconductor cells, such as a monolithically integrated diode cell, and/or a monolithically integrated transistor cell, and/or a monolithically integrated IGBT cell, and/or a monolithically integrated RC-IGBT cell, and/or a monolithically integrated MOS Gated Diode (MGD) cell, and/or a monolithically integrated MOSFET cell and/or derivatives thereof. Such diode cells and/or such transistor cells may be integrated into a power semiconductor module. A plurality of such cells may constitute a cell field that is arranged with an active region of the power semiconductor device.

The term ´power semiconductor device´ as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 400 V.

For example, the power semiconductor device described herein may be a semiconductor device exhibiting a stripe cell configuration or a cellular cell configuration and can be configured to be employed as a power component in a low-, medium- and/or high voltage application.

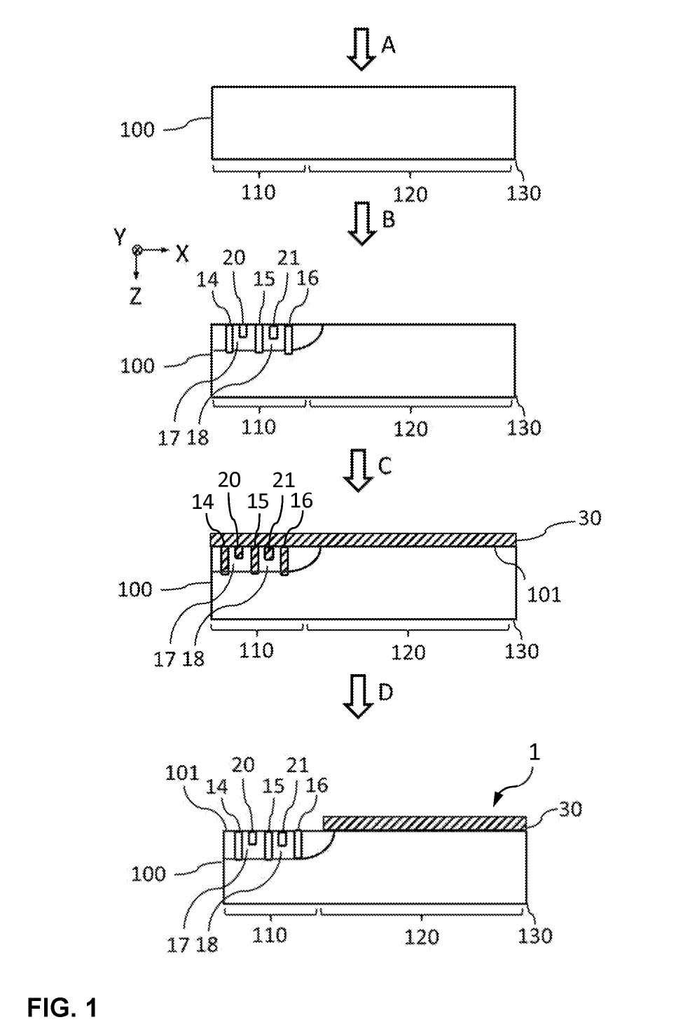

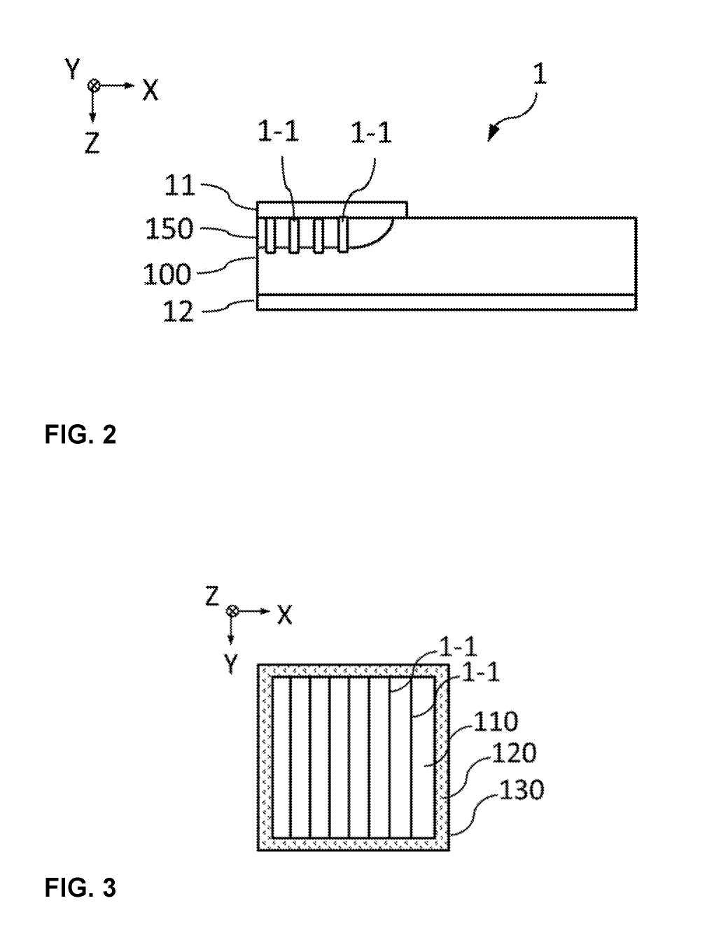

FIG. 1 exemplarily and schematically shows a method of manufacturing a semiconductor device 1. Generally, the method may start with a basic step A for providing a semiconductor body 100, a part of which is constituted as an active region 110 configured to conduct a load current, and another part of which is constituted as a termination region 120 surrounding the active region 110. An example of a semiconductor device 1 obtained by the method described herein is shown in FIGS. 2 and 3.

As schematically illustrated in FIG. 2, a vertical cross-sectional view of one section of a semiconductor device is shown. The power semiconductor device 1 comprises a semiconductor body 100 that is coupled to a first load terminal 11 and a second load terminal 12.

Regarding all embodiments disclosed herein, the power semiconductor device 1 may be an IGBT. For example, each of the embodiments shows aspects of a power semiconductor device that may be implemented so as to realize an IGBT. For example, the first load terminal 11 is an emitter terminal, and the second load terminal 12 can be a collector terminal. The semiconductor body 100 may comprise a drift region 150 with dopants of the first conductivity type. For example, the extension of the drift region 150 along the extension direction Z and its dopant concentration are chosen in dependence of the blocking voltage rating for which the power semiconductor device 1 shall be designed, e.g., in a manner as it is known to the skilled person.

Further, the first load terminal 11 may be arranged on the frontside of the power semiconductor device 1 and may include a frontside metallization. The second load terminal 12 may be arranged opposite to the frontside, e.g., on the backside, of the power semiconductor device 1 and may include, for example, a backside metallization. Accordingly, the power semiconductor device 1 may exhibit a vertical configuration. In another embodiment, each of the first load terminal 11 and the second load terminal 12 may be arranged on a common side, e.g., both on the frontside, of the power semiconductor device 1.

The power semiconductor device 1 may further include an active region 110, a termination region 120 and a chip edge 130. The semiconductor body 100 may form a part of each of the active region 110 and the termination region 120, wherein chip edge 130 may laterally terminate the semiconductor body 100. The chip edge 130 may have become into being by means of wafer dicing, for example, and may extend along the vertical direction Z. The termination structure 120 may be arranged between the active region 110 and the chip edge 130, as illustrated in FIGS. 2 and 3. The semiconductor body 100 may be comprised of a conventional semiconductor material such as, for example, silicon (Si), silicon carbide (SiC), gallium nitride (GaN) gallium arsenide (GaAs), or the like.

FIG. 3 illustrates a top view of the first surface of the semiconductor body 100 according to one example in order to illustrate a position of the active region 110 relative to the termination region 120 in the semiconductor body 100. Referring to FIG. 3, the termination region 120 surrounds the active region 110 and separates the active region 110 from the wafer edge 130. Just for the purpose of illustration, the semiconductor body 100 is rectangular in the example illustrated in FIG. 3. This, however, is only an example. According to another example (not shown) the semiconductor body 100 may be in another geometrical form, for example, may be circular.

In the present specification, the terms ´active region´ and ´termination region´ are employed in a common manner, i.e., the active region 110 and the termination region 120 may be configured to provide for the principle technical functionalities typically associated therewith. For example, the active region 110 of the power semiconductor device 1 is configured to conduct a load current between the terminals 11, 12, whereas the termination region 120 does not conduct the load current, but rather fulfills functions regarding the course of the electric field, ensuring the blocking capability, safely terminating the active region 110 and so forth, in accordance with an embodiment. For example, the termination region 120 may entirely surround the active region 110, as illustrated in FIG. 3.

The active region 110 may comprise at least one power cell 1-1. In an embodiment, there are included a plurality of such power cells 1-1 within the active region 110. The number of power cells 1-1 may be greater than 100, than 1000, or even greater than 10,000. The power cells 1-1 may each exhibit an identical configuration.

In the following, when an explanation is presented for an exemplary configuration of a specific power cell 1-1 (e.g., like ´the power cell 1-1 comprises . . . ´ or ´the component of the power cell 1-1 is/has . . . ´), this explanation may equally apply to all power cells 1-1 that may be included in the power semiconductor device 1, if not explicitly stated otherwise.

Each power cell 1-1 may exhibit a stripe configuration as schematically illustrated in FIG. 3, wherein the total lateral extension in one lateral direction, e.g., along with the second lateral direction Y, of each power cell 1-1 and its components may substantially greater than the total lateral extension in the other lateral direction, e.g., along the first lateral direction X. For example, the longer total lateral extension in the second lateral direction Y of a respective stripe power cell 1-1 may be even similar or greater than the total extension of the active region 110 along this lateral direction, as illustrated in FIG. 3.

In another embodiment, each power cell 1-1 may exhibit a cellular configuration, wherein the lateral extensions of each power cell 1-1 may be substantially smaller than the total lateral extensions of the active region 110. However, the present disclosure rather relates to embodiments of the power semiconductor device 1 in which the power cells 1-1 have a stripe configuration. Referring to all embodiments disclosed herein, each of the power cells 1-1 may exhibit a stripe configuration and can be configured to provide for an IGBT functionality.

As illustrated in FIG. 2, each power cell 1-1 may extend at least partially into the semiconductor body 100 and comprise at least a section of the drift region 150. Further, each power cell 1-1 may be electrically connected with the first load terminal 11. Each power cell 1-1 may be configured to conduct a part of the load current between said terminals 11 and 12, and to block a blocking voltage applied between said terminals 11 and 12. For controlling the power semiconductor device 1, each power cell 1-1 may be operatively coupled to or, respectively, comprise a control electrode (not shown) configured to selectively set the respective power cell 1-1 into one of a conducting state and a blocking state.

As illustrated in FIG. 1, the method further may comprise a step B of forming at least one power cell structure with a plurality of trenches 14, 15, 16 extending into the semiconductor body 100 and arranged adjacent to each other along a first lateral direction X in the active region 110. According to an exemplary embodiment each of the plurality of trenches 14, 15, 16 includes a trench electrode, wherein each of the trenches has a stripe configuration that extends along a second lateral direction Y into the active region, wherein the trenches spatially confine a plurality of mesas 17, 18.

As used herein, the term ´mesa´ may designate a section of the semiconductor body 100 that extends between two trench sidewalls of two adjacent trenches facing to each other and that has substantially the same total extension in the vertical direction Z as said two adjacent trenches.

Mesa 17 may be provided with contact holes 20 and mesa 18 may be provided with contact holes 21 (cf. FIG. 1). The contact holes 20, 21 may provide the contact of the mesas 17, 18 with the load terminal 11. Contact holes 20, 21 may be provided in some or all mesas 17, 18 within the power cell structure. The contact holes 20, 21 are aligned between the trenches 14 and 15 and 15 and 16, respectively. They are provided within the structures of mesas 17, 18. The contact holes 20, 21, generally, may have a lateral extension into the semiconductor body 100 which is about 10 to 50 %, optionally, about 20 to 40 % of the lateral extension of the trenches 14, 15, 16.

Various possibilities exist to design the power cells with regard to the neighborhood relationship (contacting schemes with respect to mesas and trench electrodes) and the respective number of first type mesa(s) 17, the second type mesa(s) 18, the first type trench(es) 14, 16 and the second type trench(es) 15. In one embodiment, it is ensured that the first type mesa 17 is spatially confined by the first type trench 14 on the one side and by a source trench 15 on the other side. Further, it can be ensured that the second type mesa 18 is spatially confined at least by one of the first type trenches 16 or that the second type mesa 18 is spatially confined by one first type trench 16 on each side. Additional structures may be comprised in the power cells and are not illustrated herein because they are known to the skilled person and highly depend on the semiconductor device to be manufactured.

In some examples, each of the plurality of trenches 14, 15, 16 may include a trench electrode (not shown in the Figures). The trench electrode may be a conductive material such as a metal. Suitable trench electrode materials are known and those known can be applied herein. The trench electrodes may be electrically insulated from the semiconductor body 100 by means of a respective trench insulator (not shown in FIG. 1). In some examples, the trench insulator may comprise or may be silicon oxide material. In preferred examples, the trench isolator comprises one or more silicon oxide layers. In the lateral direction, e.g., in the first lateral direction X, the trenches 14, 15, 16 may be terminated by respective trench side walls, and in the vertical direction Z, the trenches 14, 15, 16 may be terminated by respective trench bottom. The general profiles of trenches are known from common MPT power cell structures and can be applied herein as well.

As has been indicated above, the power semiconductor device 1 can be an IGBT, e.g., an IGBT having a micropattern-trench (MPT) structure. For example, in accordance with the MPT structure, the ratio of trench open area to mesa area is at least 30% or even more than 50%, or even more than 150% with an aspect ratio of trench depth to trench width of more than 1:3, or more than 1:5, which defines the loading conditions during trench etch. Under these conditions, the trench etch process may be sensitive to local variations in trench opening and size, and may result in a change of trench depth for varying conditions, over a single die and/or wafer. This may be an undesired effect as it may locally change the penetration of the electric field into the trench insulator in a blocking condition of the device. Such an uneven electric field may cause damage to the trench insulator of a trench section with increased trench depth, potentially impacting device performance and/or quality and/or reliability. Hence, it is desired to minimize variations in trench size and opening dimensions.

Further, in accordance with the MPT structure, each of the trenches 14, 15, 16 that may be included in the power cell 1-1 may exhibit substantially equal spatial dimensions and may be arranged in accordance with a regular pattern. For example, each of the trenches 14, 15, 16 may exhibit a depth along the vertical direction Z within the range of 1 µm to 50 µm, for example 3 μm to 8 μm, and a width along the first lateral direction X within the range of 0.1 to 2 µm, for example 0.4 μm to 1.6 μm. Further, each of the trench electrodes of all trenches 14, 15, 16 that may be included in the at least one power cell 1-1 may substantially exhibit equal spatial dimensions. In addition, each of the trenches 14, 15, 16 that may be included in the at least one power cell 1-1 can be arranged equidistantly along the first lateral direction X. For example, each of the first type mesa 17 and the second type mesa 18 of each power cell 1-1 may exhibit the same width in the first lateral direction X, which may be within the range of 1 µm to 50 nm, for example within the range of 0.1 μm to 0.3 μm, within the range of 0.3 μm to 0.8 μm, or within the range of 0.8 μm to 1.4 μm. The contact holes 20 within the mesas 17, 18 may have a lateral extension in the direction Z of about 0.1 µm to 0.5 µm. Further, the MPT-IGBT may include a plurality, e.g., more than 100, of such equally configured power cells 1-1.

As described herein, method step B results in the formation of at least one power cell structure having a Micro Pattern Trench (MPT) area in the active area comprised of several power cells 1-1 as described hereinbefore. Due to the complexity of the MPT contact hole size and trench profile, the common processing techniques used in typical products with larger contacts and profiles presents challenges for the following manufacturing processes. The formation of a charge shielding layer (CSL) may play a critical role at the edge termination region 120. Within the active region 110, however, a charge shielding layer has no purpose and usually should be avoided by either using a selective deposition step or by removing it after the deposition. Any presence of a charge shielding layer or, more generally, of a passivation layer in the active region may lead to device failures. As in a typical process, a passivation layer would be positioned after the metallization process, that means after the filling of the contact holes or trenches with a conductive material such as a metal. The passivation layer formation above the metal layer forming step would not allow the contact formation of the passivation layer at the junction termination. Hence, careful consideration of factors such as annealing temperature, structuring of trench isolating material such as silicon oxide, metallization, passivation, and more would be necessary. Hence, the complexity of the MPT contact hole size and profile results in challenges in the forming and removing of the passivation layer at the active region, especially at the MPT cell structure region.

As has been illustrated in FIG. 1, the method may comprise a further step C, namely forming a charge shielding layer 30 on the first surface 101 comprising the at least one power cell structure within the active region 110 and the termination region 120. As the active region 110 with the power cells is not yet provided with a metallization layer, the material of the charge shielding layer 30 fills the holes of the first, second, and further trenches 14, 15, 16 as well as of the contact holes 20, 21 optionally provided at the first surface 101 of the active region 110 for contacting the mesas 17, 18.

In accordance with an embodiment, the method further comprises a step D wherein the charge shielding layer 30 may be removed from the first surface 101 at least in the region of the power cell structure in the active region 110.

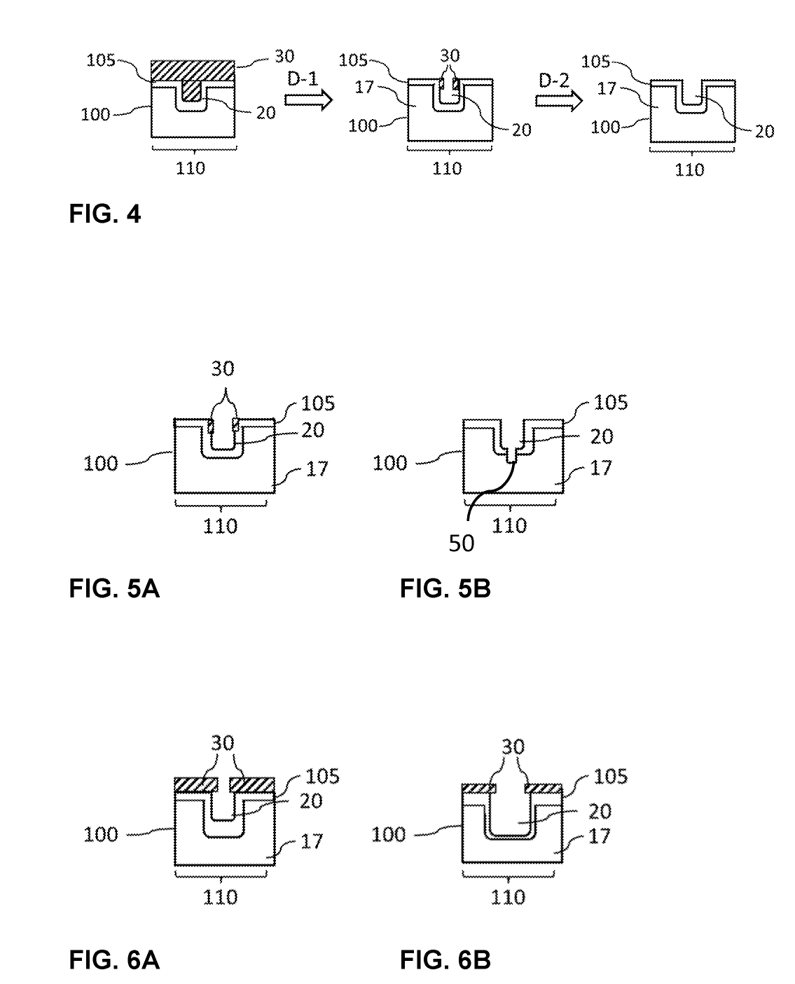

As illustrated in the embodiment shown in FIG. 4, the etching step D is illustrated in detail in the region of one of the contact holes 20 provided in the active region 110 of the semiconductor body 100 (cf. FIG. 1). The contact hole is prepared within the surface layer of the semiconductor body 100 and the side walls as well as the bottom wall of the contact hole 20 are provided with an insulating layer 105. For example, the insulating layer may be a stack of one to three silicon oxide layers with different structures. For simplicity, the three layers are not separately shown in the figures, but the description includes such a complex insulating silicon oxide layer structure while showing one silicon oxide layer 105 as exemplifying embodiment only. After the deposition of the charge shielding layer 30 over the first surface of the semiconductor body 100, parts of the charge shielding layer 30 in the active region 110 may be removed by applying a first etching process D-1 to the charge shielding layer 30. The etching process may be carried out until the contact holes 20 of the power cell structure are open. According to some embodiments, the etch rate for Si or SiC etching of the etching process D-1 used is high. Therefore, the detection of oxides in the etching atmosphere may be used to indicate that the charge shielding layer 30 has been etched away in at least some parts of the semiconductor device. This can be used as a detection point for stopping the first etching process D-1 with high etching rates. As can be seen in the middle section of FIG. 4, most parts or all parts of the charge shielding layer 30 at the bottom or the side walls of the contact holes 20 have been removed by the first etching.

It was noticed that no etching method of the commonly used and applicable etching methods revealed a removal of the charge shielding layer in a sufficient manner. It is assumed that the size and profile of the contact holes and of the trenches of an MPT power cell structure is responsible for these results. If a unidirectional etching, e.g. anisotropic etching, has been used, the charge shielding layer 30 could be removed from the contact holes 20 and/or trenches, but the etching process was not satisfactory at the curvature area at the contact hole entrance, that means near the first surface of the semiconductor body of mesas 17. Some residuals of the charge shielding layer 30 especially remain at these parts of the contact holes 20 (cf. FIG. 5A). Extending the etching time to fully remove the residues at the curvature area, however, causes over etching (50) into the semiconductor body 100, e.g. the silicon or silicon carbide layer. Such over etching into the semiconductor body 100 may be observed at the bottom of the contact holes 20 and mostly is observed with total removal of the insulating layer 105. Similarly, an isotropic etching did not completely remove the charge shielding layer 30 on the contact hole 20 and/or trench and/or the mesas 17 between the trenches (cf. FIG. 6A). Extending the time of the isotropic etching to remove charge shielding layer material completely from the contact hole 20 or mesas 17 may cause massive over etching of at least the insulating layer 105 causing a reduction of the insulation effect. In extreme cases it may result in an etching into the semiconductor body 100. As shown in FIG. 6B, the bottom and side walls of the contact holes 20 in the active region 110 may be enlarged by reducing the insulating layer 105, while still some charge shielding layer material 30 remains on the curvatures of the contact holes 20 or the surface of the mesas 17.

In the light of the above observations, the first etching process D-1 may be selected from an anisotropic etching method and the time and etching procedure may be carried out such that most parts or all parts of the charge shielding layer 30 at the bottom or the side walls of the contact holes 20 have been removed by the first etching (cf. FIG. 4, middle part). According to the method described herein, it is possible to detect oxide concentration in the atmosphere during the etching process and to stop the first etching if an oxide concentration is detectable by the detection method used. The oxide which can be detected may result from one or more silicon oxide layers 105 provided between the semiconductor substrate 100 and the charge shielding layer 30. This endpoint detection may be used to limit or to avoid significant loss of semiconductor material within the trench structures and within the contact holes and at the surface of the semiconductor body 100 within the mesas. Therefore, the overall MPT power cell structure may be protected from significant changes during the etching processes used for removing the charge shielding layer within the active area 110.

According to an embodiment of the method described herein, the removing step D further comprises applying a second etching process D-2 different to the first etching process to the charge shielding layer 30 remaining after the first etching D-1. In this second etching process, the residuals of the charge shielding layer 30 may be removed from the first surface in the region of the power cell structure. In some examples, the second etching process D-2 is selected such that the etching rate of Si or SiC material components is low. This allows to increase the selectivity of the etching process to the charge shielding layer materials. Thus, the method describes a two-step removing process for completely removing the charge shielding layer material 30 from the contact holes 20 and/or the trench 14 and the mesas 17 between the trenches in the active region 110. The method is adapted to a low-sized structure of power cells, even if MPT power cells with low sizes and profiles are provided. At the same time when the two-step etching process is applied to the active area 110, the charge shielding layer 30 may remain in the structure of the termination region 120.

In an example, the charge shielding layer at the termination region 120 may be protected from etching processes by photolithography. Therefore, while completely removing the charge shielding layer in the active region 110 as described above, a photomask will protect the termination region 120 such that the charge shielding layer 30 and an optional silicon oxide containing layer or an additionally provided semi-insulating nitride layer or other ion blocking layers (e.g. amorphous SiC (aSiC) and/or hydrogen rich amorphous SiC (aSiCH) or diamond like carbon (DLC)) remain on the first surface of the termination region 120. Providing a charge shielding layer at the termination region may play a critical role and may ensure reliability performance, for example in scenarios like High Temperature Reverse Bias (HTRB), where it effectively blocks external ions that could disrupt the electric field. Such disruptions of the electric field may cause avalanche breakdowns within the semiconductor device.

According to an embodiment, the first etching process D-1 may be an anisotropic etching method. In some examples the first etching process, e.g. the anisotropic etching process, is stopped before the material at the bottom of the contact hole of the power cell structure, that means the semiconductor body material (e.g. Si, SiC) is significantly affected by the etching process. To stop the etching before the semiconductor body material is etched, one or more silicon oxide layers may be provided between the semiconductor body material and the charge shielding layer. If the charge shielding layer is removed completely at one part of the power cell structure, the silicon oxide may be etched, and oxides may be measured in the atmosphere. As soon as oxides are detected the first time or an oxide concentration threshold is reached in the etching atmosphere the etching process D-1 may be stopped before the oxide is completely removed. In addition to an endpoint detection of the etching process, when using anisotropic etching as the first step, the processing time, pressure, chemicals, and other etching parameters are selected such that the trench profile and size is not significantly changed during the etching process and the trench walls constituted of the semiconductor material and the oxide material in the silicon oxide layer(s) provided thereon are not affected significantly. Slight material removal may be tolerated but shall be minimized as much as possible by adjusting and observing the etching duration. Endpoint detection and optimization may be applied during the first etching process. The endpoint may be selected such that the trench and contact hole size and profile is not significantly changed during the etching, but some residual leftovers of the charge shielding material, e.g. at the curvature (also called ‘space areas’), may be acceptable, even if the amount is significant. Leftovers of the charge shielding layer material at these areas may be removed in the second etching process D-2.

According to some examples, the second etching process D-2 is different to the first etching process. For example, if an anisotropic etching process is used in Step D-1, then an isotropic etching method may be applied in the second etching process step D-2. In some examples, the first etching process D-1 is an anisotropic etching method, followed by an isotropic etching method as second etching process D-2. Thus, in some examples, for the etching process D-1 the processing time, pressure, chemicals, and other etching parameters are selected such that the oxide in the trench profile is not significantly changed during the etching process and for the etching process D-2 the processing time, pressure, chemicals, and other etching parameters are selected such that the oxide in the trench profile is not completely removed and additionally the trench walls constituted of the semiconductor material (Si or SiC) are not affected significantly. Furthermore, the silicon oxide layer(s) can be used as a means for controlling the etching process D1- as explained before. The concentration level of oxide components may be used for detecting the end point of the etching process D-1, for example.

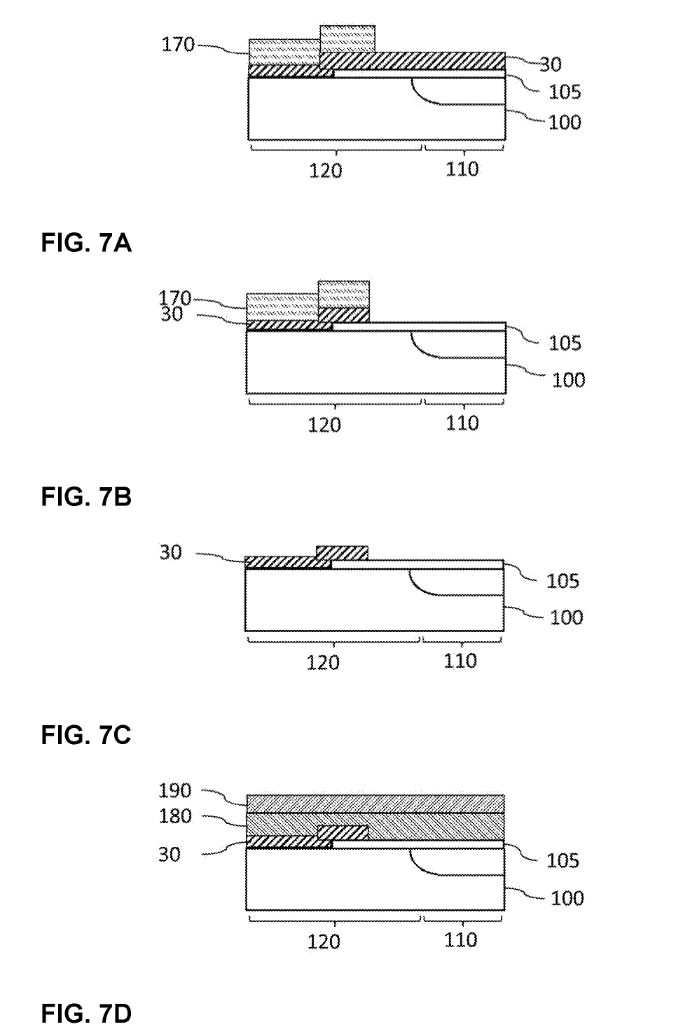

According to some examples, the charge shielding layer comprises a semi-insulating layer selected from a semi-insulating nitride layer, a silicon nitride layer, a DLC (diamond like carbon) layer, an aSiC (amorphous SiC) or aSiCH (hydrogen-rich amorphous SiC) layer, or any combination of these layers. In some examples, the silicon nitride layer may be formed by silico-rich silicon nitride materials. In other examples, e. g. in the example shown in FIG. 7A, a protective layer for improving barrier functionality may be formed by an oxide layer 105 followed by a charge shielding layer 30, e.g. a silicon nitride layer (e.g. SiSiN). The silicon oxide layer 105 may be formed in a separate deposition step before the deposition of the charge shielding layer 30 or may be formed during the deposition of the charge shielding layer 30. In some examples, two different nitride layers may be deposited, for example a charge shielding layer 30 based on silicon nitride and a more Si enriched SiSiN layer wherein the second nitride layer acts as passivation layer, for example. Such an embodiment is shown in FIG. 7A showing the layer stack at the termination region only while the details in the active area have been not shown, but usually is an MPT power cell structure. Usually, these layer stacks as described above provide a charge shielding effect but also have the function of a passivation layer (ion barrier functionality, e.g. for Na atoms) at the same time. In the embodiment shown in FIG. 7A, the charge shielding layer 30 is already provided with a photosensitive mask 170 for the etching steps. The mask 170 is provided at the termination region 120 in such portion which should be protected by the charge shielding layer in the semiconductor device while the charge shielding layer 30 is etched away from the active region 110.

In FIG. 7B, the termination region of the same device is shown after the two etching steps. The mask 170 has protected the charge shielding layer 30 at most or all parts of the termination region 120, while the charge shielding layer has been etched away at the parts of the active region 110 of the semiconductor device. The etching has been carried out as long as the silicon oxide layer 105 has been protected by the charge shielding layer. At the end of the mask 170, a stack comprising the silicon oxide layer 105, the charge shielding layer 30 and the mask has been left at the surface of the semiconductor body 100.

In FIG. 7C, the same semiconductor device has been shown in cross-sectional view, but without the photosensitive mask layer.

FIG. 7D shows the final product at the termination region 120 comprising the charge shielding layer (partly over the remaining silicon oxide layer 105) at the surface of the semiconductor body 100, together with a silicon oxide layer 180 and silicon nitride layer 190 provided over the charge shielding layer 30 and the silicon oxide layer 105 partly present in the termination region 120.

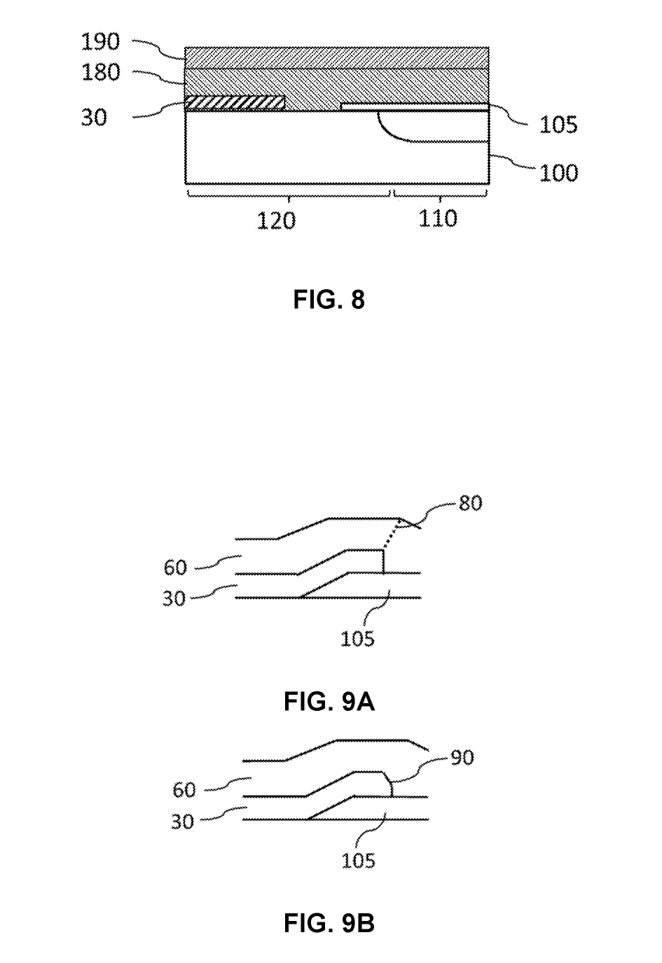

Alternatively, some embodiments of the semiconductor device do not have a silicon oxide layer 105 within the remaining area in which the charge shielding layer 30 is provided for protecting the termination region 120. Such an alternative embodiment is shown in FIG. 8 after a silicon oxide layer 180 and a silicon nitride layer 190 have been provided over the termination region 120 and active region 110.

During a two-step etching process, the isotropic and anisotropic etching processes have a different influence at the edge of the charge shielding layer 30. For example, much more of the upper portion of the charge shielding layer 30 may be etched away during an anisotropic etching only because of the high reactivity of the anisotropic etching. Moreover, in a one-step etching process as commonly used, the etching time is usually much longer than in the two-step process described herein and a vertical edge at the end of the charge shielding layer is obtained (cf. FIG. 9A). The vertical edge at the charge shielding layer may result in a seamline 80 within the silicon oxide/silicon nitride layer 60 in the final product. Thie seamline 80 may result in breakdowns of the semiconductor devices, for example by providing a pathway for leakages.

If an anisotropic and an isotropic etching process is combined to fully remove the charge shielding layer in the contact holes and trenches of the active region 110, then the profile at the edge (in its cross-sectional view) usually is provided with a smoother edge. Sometimes, a notch at the top of the charge shielding layer 30, that means at the right side between the upper surface of the charge shielding layer 30 and the additional silicon oxide/silicon nitride layer stack 60 in FIG. 9B is obtained. This notch can be used to distinguish the etching methods used for manufacturing the semiconductor device. Moreover, if such a smooth edge is prepared during the etching process, e.g. a notch remains, then the overlaying silicon oxide/silicon nitride layer 60 usually does not show a seamline. Hence, this improves the reliability of the semiconductor devices prepared according to the method described herein.

In some examples, the edge of the charge shielding layer 30, e.g. the silicon nitride layer provided above the silicon oxide layer 105, may be in contact with the silicon oxide layer 105 as, e.g. shown in the embodiment illustrated in FIG. 7D. In another example, e.g. illustrated in FIG. 8, the silicon oxide layer 105 provided over the active region 110 does not extend to the edge of the charge shielding layer 30.

In some examples, the charge shielding layer is deposited in a thickness of about 100 nm to 1.5 µm, in some examples of about 66-900 nm, for example at least about 800 nm.

The semiconductor devices manufactured according to the method described herein may be characterized by humidity robustness and long-term blocking stability for most power semiconductor devices. Moreover, they have the potential to increase the lifetime of the semiconductor devices, the yield in the manufacturing of the semiconductor devices and enable subsequent humidity and reliability rugged MPT products. Compared to diamond like carbon made charge shielding layers and common etching processes, for example, the charge shielding layers and the semiconductor products obtained by the methods as described herein may increase the maximum allowed junction temperature in high voltage power semiconductor devices with good long-term blocking stability.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including their preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A method of manufacturing a semiconductor device, the method comprising:
providing a semiconductor body comprising a part of each of an active region configured to conduct a load current and a termination region surrounding the active region, the semiconductor body having a first surface;
forming at least one power cell structure with a plurality of trenches extending into the semiconductor body and arranged adjacent to each other along a first lateral direction in the active region at the first surface, wherein each of the plurality of trenches includes a trench electrode, each of the trenches has a stripe configuration that extends along a second lateral direction into the active region, and the trenches spatially confine a plurality of mesas comprising contact holes;
forming a charge shielding layer on the first surface comprising the at least one power cell structure within the active region and the termination region;
removing the charge shielding layer from the first surface at least in the region of the power cell structure by:
applying a first etching process to the charge shielding layer at least until the trenches and/or contact holes of the power cell structure are open; and
applying a second etching process different to the first etching process to the charge shielding layer remaining after the first etching, to remove residuals of the charge shielding layer from the first surface in the region of the power cell structure.

2. The method of claim 1, further comprising forming a first load terminal on the first surface and a second load terminal on a second surface, wherein the active region is configured to conduct the load current between the first load terminal and the second load terminal.

3. The method of claim 1, further comprising protecting the termination region from etching by photolithography.

4. The method of claim 1, wherein the first etching process is an anisotropic etching method.

5. The method of claim 1, wherein the first etching process is stopped before a material at the bottom of the trench and/or the contact hole of the power cell structure is significantly removed.

6. The method of claim 1, wherein the second etching process is an isotropic etching method.

7. The method of claim 1, wherein the first etching process is an anisotropic etching method, followed by an isotropic etching method as the second etching process.

8. The method of claim 1, wherein the charge shielding layer comprises a semi-insulating layer selected from the group consisting of: a silicon nitride layer; an amorphous SiC layer or diamond like carbon layer; and any combination of these layers.

9. The method of claim 1, further comprising an oxide layer followed by the charge shielding layer in the active region of a power cell structure.

10. The method of claim 1, wherein the power cell structure is formed in a stripe shape trench mesa pattern comprising parallel trenches and parallel mesas.

11. The method of claim 1, wherein a maximum width of each of the mesas is between 0.2 and 2 µm.

12. The method of claim 1, wherein the power cell structure further comprises contact holes within the active region, and wherein a depth of the contact holes is in a range of 50 nm to 1 µm.

13. The method of claim 1, wherein the charge shielding layer is deposited in a thickness of 100nm to 1.5µm.

14. The method of claim 1, wherein a silicon oxide layer is formed on the semiconductor body before or during the deposition of the charge shielding layer.

15. The method of claim 14, wherein an edge of the charge shielding layer is in contact with the silicon oxide layer.

16. A semiconductor device formed by the method of claim 1.
